(19) United States
(12) Patent Application Publication
(10) Pub. No.: US 2026/0005084 A1
(43) Pub. Date: Jan. 1, 2026

(54) Microelectronic Glass-Containing Core Layer Including Clamp Structure

(71) Applicant: Intel Corporation, Santa Clara, CA (US)

(72) Inventors: Jeremy D. Ecton, Gilbert, AZ (US); Brandon Christian Marin, Gilbert, AZ (US); Srinivas Venkata Ramanuja Pietambaram, Chandler, AZ (US); Gang Duan, Chandler, AZ (US); Suddhasattwa Nad, Chandler, AZ (US); Shaojiang Chen, Gilbert, AZ (US); Leonel R. Arana, Phoenix, AZ (US); Matthew L. Tingey, Mesa, AZ (US); Benjamin T. Duong, Phoenix, AZ (US); Bohan Shan, Chandler, AZ (US); Manohar Konchady, Chandler, AZ (US); Yekan Wang, Chandler, AZ (US); Andrew Matthew Jimenez, Mesa, AZ (US)

(73) Assignee: Intel Corporation, Santa Clara, CA (US)

(21) Appl. No.: 18/758,561

(22) Filed: Jun. 28, 2024

(51) Int. Cl. H01L 23/15; H01L 23/00; H01L 23/498; H01L 25/065

(52) U.S. Cl. CPC H01L 23/15; H01L 23/49816; H01L 23/49822; H01L 24/16; H01L 25/0652; H01L 2224/16235

(57) ABSTRACT

A core layer of a package substrate includes a dielectric layer; a glass sheet encapsulated in the dielectric layer; and a clamp structure including a through-via extending through the sheet, a top plate structure connected to a top end of the through-via, and a bottom plate structure connected to a bottom end of the through-via, wherein one of: the top plate structure and the bottom plate structure have respective lateral end surfaces that are substantially flush with a lateral edge surface of the core layer; or the through-via is a first through-via, the core layer includes a block at an edge region thereof that defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via.

### BACKGROUND

Glass core panel structures, because of their brittle nature, are currently embedded in an organic frame through a reconstitution process. The organic frame encapsulates the glass and protects its edges from direct contact with processing toolsets for the further processing of the reconstituted panel. Instead, the processing toolsets can grip the organic frame instead of the glass core panel structures, in this way preventing direct contact with the glass sheets within the core panel structures. After processing the core panel structures are singulated to form core layers therefrom, which may be used as part of package substrates for the formation of microelectronic assemblies, such as multi-chip assemblies.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a cross sectional view of a microelectronic assembly including a core layer according to a first embodiment.

FIGS. 2A-2E show respective stages of fabrication of respective panel structures to result in a reconstituted panel structure (RPS) ready for singulation to form glass containing core layers therefrom.

FIG. 3A is a partial cross-sectional view of a core layer according to a second embodiment.

FIG. 3B is a simplified top plan view of a RPS which, after singulation, may result in a plurality of core layers similar to the core layer of FIG. 3A.

FIGS. 4A and 4B are respective partial cross-sectional views of a core layer according to respective first and second options of a third embodiment.

FIG. 5A is a partial cross-sectional view of a core layer according to a fourth embodiment.

FIG. 5B is a cross sectional view across plane parallel to and between a top surface and a bottom surface of an RPS, where the RPS includes a plurality of core layer structures at the perimeter thereof that would yield, after singulation, core layers similar to the core layer of FIG. 5A.

FIG. 6 is a partial cross-sectional view of a core layer according to the state of the art.

FIG. 7 is a flow chart of a process according to some embodiments.

FIG. 8 is a cross-sectional side view of an integrated circuit device assembly that may include a core layer in accordance with any of the embodiments disclosed herein.

FIG. 9 is a block diagram of an example electrical device that may include a core layer in accordance with any of the embodiments disclosed herein.

### DETAILED DESCRIPTION

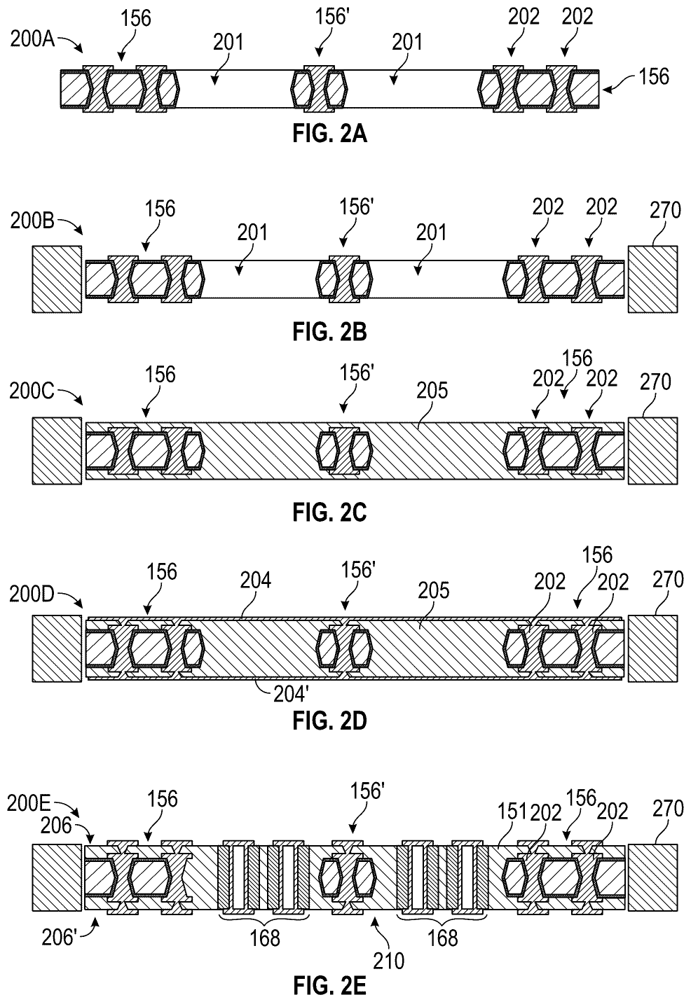

Glass-cored panels including one or more core layers are currently not entirely suitable for existing organic processing due to their brittle nature, making them highly prone to breaking during the handling and mechanical processing involved, such as in Desmear or Electroless operations. Some existing solutions propose embedding the glass core panel into an organic frame through a reconstitution process, which fully encapsulates the glass and protects its edges from direct contact with the processing toolsets (e.g., as will be explained in relation to FIGS. 2A-2D below). However, this method presents a concern, particularly for thin core processing, due to the risk of gap interface cracking or debonding caused by increased warpage and reduced stiffness of the embedded glass sheet.

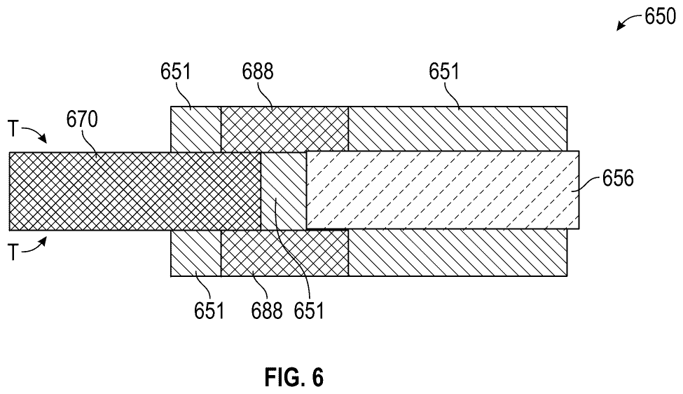

There is currently no known high-volume manufacturing (HVM) solution for handling glass core panels or layers during processing in a manner that substantially minimizes delamination between the glass and the encapsulation material within which it is embedded. Presently, a hybrid architecture is being explored for thick core manufacturing, where the glass is embedded into a frame and reinforced with glass-cloth prepreg or copper, as will be explained in more detail in relation to FIG. 6 below.

Therefore, a solution to enhance and strengthen the bond between the glass sheets of a core panel/glass-containing panel substrate and the organic frame, especially for thin core applications and processing, is being proposed herein.

Some embodiments include core layer of a package substrate, the core layer including a dielectric layer, a sheet including glass, the sheet encapsulated in the dielectric layer; structures defining electrically conductive pathways within the core layer; and a clamp structure including a through-via extending through the sheet, a top plate structure connected to a top end of the through-via, and a bottom plate structure connected to a bottom end of the through-via. According to a first embodiment, the top plate structure and the bottom plate structure have respective lateral end surfaces that are substantially flush with a lateral edge surface of the core layer. According to a second embodiment, the through-via is a first through-via, the core layer includes a block at an edge region thereof, the block defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, reference to a “die” is meant to broadly refer to a die, a chiplet, a chip complex, a chiplet complex, or any other integrated circuit structure including circuitry therein supported on a substrate. While the terms die, chip, and chiplet may be used interchangeably, the term chiplet is sometimes used to refer to an integrated circuit die that implements a subset of the functionality of a larger integrated circuit component, the larger integrated circuit component formed using one or more chiplets connected by inter-die interconnects (e.g., interposers, bridges, local interconnect components, local silicon interconnects). The use of chiplets in integrated circuit components has become attractive as feature sizes have reduced and the demand for high-performance larger integrated circuit components has increased. The approach of assembling multiple known-good dies (chiplets) to form a larger integrated circuit component results in improved manufacturing efficiencies as the overall yield of an integrated circuit component assembled from multiple small chiplets is better than that of an integrated circuit component in which the functionality of the chiplets is implemented on a single large integrated circuit die. Any integrated circuit die, chip, or chiplet can implement any portion of the functionality of any processor unit described or referenced herein.

As used herein, the term “electronic component” can refer to an active electronic circuit/active electronic component (e.g., processing unit, die, chiplet, memory, High Bandwidth Memory (HBM), storage device, FET, etc.) or a passive electronic circuit/passive electronic component (e.g., resistor, inductor, capacitor, etc.).

As used herein, the term “active” or “electrically active” when referring to a region of a semiconductor structure or microelectronic structure refers to a region of such structure that is configured to conduct electricity. “Active” in the context of a semiconductor/microelectronic structure, or in the context of an electronic component (e.g., an “active” component versus a “passive” component), is not meant to necessarily be construed as referring to a device in operation.

As used herein, the term “the material” of component A may refer to one or more constituent materials of component A. For example, where component A includes 3 sublayers made of three respective materials X, Y and Z, the disclosure herein may refer to “the material of component A” to refer to materials X, Y and Z that make up component A.

As used herein, the term “integrated circuit component” can refer to an electronic component on a semiconducting material configured to perform a function. An integrated circuit (IC) component can comprise one or more of any electronic components, such as any electronic components described or referenced herein, or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

As used herein, “pitch” may be measured center-to-center between two elements (e.g., from a center of a through-via to a center of an adjacent through-via).

As used herein, “contacts” may refer to electrically conductive structures of or on a first microelectronic component (e.g., an electronic component, a substrate, a panel layer, etc.) that may be electrically coupled to contacts of a second microelectronic component. Contacts may include, for example, solder balls, pads, or pins.

“Electrically conductive structures” as used herein may include an electrically conductive material such as a metal (e.g., copper, aluminum, nickel, cobalt, iron, tin, gold, silver, or combinations thereof). Examples of electrically conductive structures may include traces, which extend horizontally, and vias, which extend vertically.

As used herein, the term “electrically conductive pathway” refers to electrically conductive structures such as traces, vias, contacts, metallization layer coatings, metallization layers, contacts (e.g., solder balls, pads, pins, pillars, etc.).

“Hybrid bonding” as used herein may refer to a process involving direct metal to metal and dielectric to dielectric bonding between two electronic components. In hybrid bonding, the metallic bonds and dielectric bonds may occur without the use of solder materials, and there may be an absence of underfill material as well. Some hybrid bonding may result in metal grain interdiffusion at a hybrid bonded interface between two hybrid bonded contacts. Some hybrid bonding may make use of a dielectric material on metal contacts of a first electronic component to be hybrid bonded to a second electronic component. In such a case, a hybrid bonded connection between the first and second electronic components may include the metal, and also some elements of the dielectric material, such as at least one of silicon and oxygen. For hybrid bonding, an organic dielectric, such as polyimide (PI) may be used. In the case of the latter, the hybrid bonded connection may include the metal, and some elements of an organic dielectric material, such as PI.

By “A is embedded in B,” what is meant herein is that B at least partially covers side surfaces of A, and at most covers all surfaces of A.

A non-limiting example of an unpackaged integrated circuit component includes a single monolithic integrated circuit die (shortened herein to “die”); the die may include solder bumps attached to contacts on the die, or contacts on the die can allow the die to be hybrid bonded to other contacts on other devices, such as on a package substrate. When present on the die, the solder bumps or other conductive contacts can enable the die to be directly attached to a printed circuit board (PCB) or other substrates.

An existing example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

For convenience, a phrase referring to element “X,” where X is a reference numeral, may be used to refer to any one of elements XA or XB if such elements have been disclosed.

A core layer, a package substrate including the core layer, a microelectronic assembly, and related devices and methods, are disclosed herein.

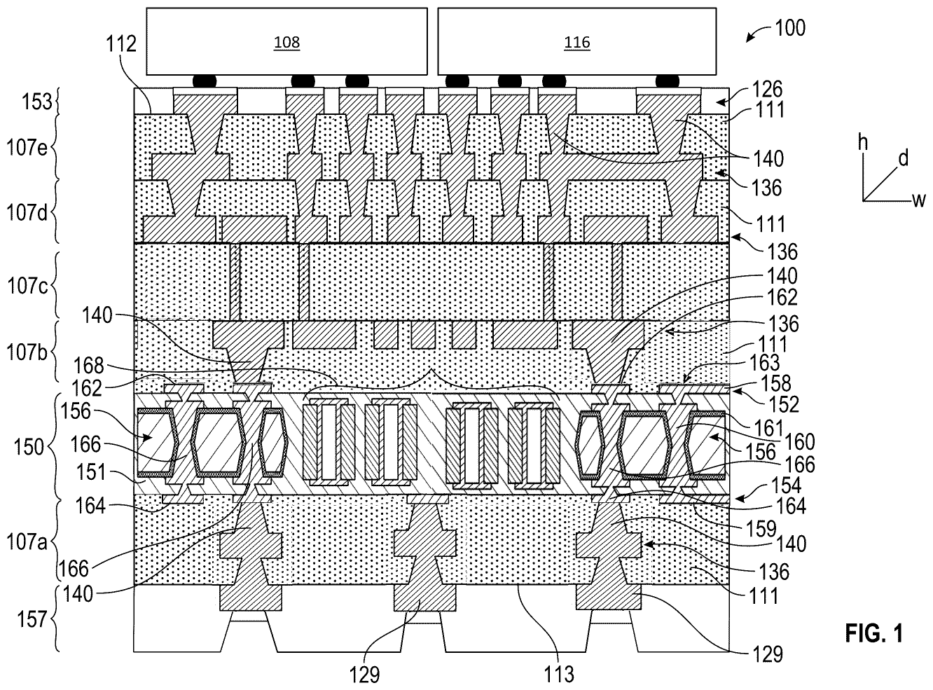

FIG. 1 is a cross-sectional view of an example microelectronic assembly 100 according to a first embodiment. Package substrate 104, includes redistribution layers (RDLs) or build-up layers 107a-107e, and a core layer 150. The package substrate 104 corresponds to a microelectronic structure.

Persons with skill in the art may appreciate that the distinctions in the various build-up layers attributed to the build-up layers 107a-107e in this discussion have been introduced for illustrative purposes; in a cross-sectional image of the package substrate 104, such as by a transmission electron microscope (TEM), the layers 107a-107e may be indistinguishable, and different from the ones shown in the figure, and there may be more or less of the build-up layers than the ones shown.

Electrically conductive structures provide signal communication for die 108 and for die 116, and throughout the microelectronic assembly 100, through and within core layer 150, and, as seen at build-up layer 107a, conductive contacts 129 that may couple the microelectronic assembly to a motherboard or other circuit component. Electrically conductive structures of the package substrate 104 may include traces 136 (including for example contacts), and vias 140. Traces 136 may be arranged to route electrical signals in a horizontal direction, and vias 140 may be arranged to route electrical signals in a vertical direction. The electrically conductive structures may include an electrically conductive material such as a metal (e.g., copper, aluminum, nickel, cobalt, iron, tin, gold, silver, or combinations thereof). A passivation layer 153 in the form of solder resist or other dielectric material on the upper substrate surface 112 of package substrate 104 may be patterned with a respective pinouts (physical arrangement of conductive contacts 126 at a respective pitch) for individual dies such as dies 108 and 116. A passivation layer 157 in the form of solder resist or other dielectric material on the lower substrate surface 113 of package substrate 104 may also be patterned with a respective pinouts (physical arrangement of conductive contacts 129 at a respective pitch) for electrical coupling of the microelectronic assembly 100 to another component, such as a motherboard. The buildup layers may further include a non-conductive material 111 within which the traces 136 and vias 140 may be embedded.

The build-up layers 107a-107e, although shown in FIG. 1 (and in some subsequent figures herein) as a handful of layers, can include any number of build-up layers or sublayers. For example, in server applications, there can be up to 10 build-up layers. In various embodiments, a build-up layer comprises a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a build-up layer comprises a photo-imageable dielectric (PID). In some embodiments, a build-up layer may comprise an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties of the build-up layers (e.g., the dielectric constant (Dk), and/or dissipation factor (insertion loss) (Df)).

In some embodiments, it is advantageous for the build-up layers to have a CTE that matches that of integrated circuit dies (e.g., match the CTE of silicon) attached to the package substrate. In some embodiments, the dielectric material of a build-up layer can have a CTE that is close (e.g., within 10%) to that of silicon. In other embodiments, the dielectric material of a build-up layer can be any type of epoxy molding compound. Build-up layers may include a metal layer comprising conductive traces (or metal lines), metals used for interconnect metals in the build-up layer may include copper or other suitable metal.

Package substrate 104 as shown corresponds to a microelectronic structure in the form of a printed circuit board that may include a core layer 150. The core layer 150 may correspond to a core substrate, and may be disposed in a region of the package substrate 104 between top and bottom build-up layers of the latter.

The core layer 150 may include a layer including a dielectric material (hereinafter, a “dielectric layer”) 151, which may include, for example, a mold compound. The mold compound may include one or more insulating materials, such as, for example, at least one of a thermosetting resin such as an epoxy resin, a thermoplastic resin such as polyimide, or a material including the thermosetting resin and the thermoplastic resin, a glass fiber (or a glass cloth or a glass fabric, an inorganic filler, and/or a reinforcing material such as an inorganic filler, for example, a copper clad laminate (CCL), an unclad CCL, or the like). Alternatively, the mold compound may include, for example, a liquid crystal polymer (LCP). Where bonding layers are used as part of the mold compound, they may include, for example, at least one of a thermosetting resin such as an epoxy resin, a thermoplastic resin such as polyimide, or a material including the thermosetting resin and the thermoplastic resin, a glass fiber, and/or a reinforcing material such as an inorganic filler, for example, prepreg (PPG), Ajinomoto Build-up Film (ABF), and the like.

The core layer may further include a sheet including glass (hereinafter “glass sheet”) 156, the glass sheet 156 defining holes therein, such as through holes as shown to receive vias therein, such as through-vias 160 and 166. According to some embodiments, the core layer 150 may include one or more glass sheets similar to glass sheet 156 of FIG. 1.

The glass material of the glass sheets 156 within core layer 150 may include silicon, and, in addition, optionally at least one of oxygen or boron. For example, the glass material may include silicon, oxide, silicon dioxide, or a borosilicate material.

The glass sheet 156 may correspond, as suggested in FIG. 1, to a sheet of glass that is perforated, for example through drilling, to provide through-holes therein for the provision of through-vias 160 and 166. The sheet of glass of each of the glass sheets 156 may be clad in a buffer layer 161 to prevent cracking. The buffer layer 161 may, for example, include silicon nitride or parylene.

The core layer 150 may further include various active electronic components or passive electronic components therein. In the shown embodiment of FIG. 1, example electronic components in the form of coaxial metal inductor loops (Coax Mils) 168, substrate-level inductor architectures, four of which are shown in FIG. 1 by way of example. Active components may include, for example, dies embedded in the core substrate. Passive components may include, for example, resistors, capacitors, and/or inductors. The core layer 150 may further include interconnect bridges therein, either active ones or passive ones.

Core layer 150 further includes electrically conductive pathways. The electrically conductive pathways of core layer 150 correspond to electrically conductive traces and vias within the cores layer that are to conduct electrical signals within and through the core layer 150 when the microelectronic assembly 100 of FIG. 1 is in operation. The electrically conductive pathways of the core layer 150 are thus to conduct electrical signals within active (electrically active) regions of the core layer 150. The electrically conductive pathways of the core layer 150 include, for example, traces 162 and through-vias 166, and further, any electrically conductive pathways to and from any active or passive components of the core layer 150.

Core layer 150 further includes, at the right lateral edge thereof, as shown in FIG. 1, a clamp structure 170 that includes through-via 160, top plate structure 158 connected to a top surface of through-via 160, and bottom plate structure 159 connected to a bottom surface of through-via 160. It is to be understood that core layer 150 may include, beside glass sheet 156 at the left side thereof, other one or more glass sheets (not shown) which are free from a clamp structure therein. The core layer 150 of FIG. 1 may, for example, be provided after a dicing of a reconstituted core layer panel including a glass containing core substrate and an organic frame framing the glass containing core substrate, as will be explained in further detail in relation to FIGS. 2A-2C

In the shown embodiment of FIG. 1, the top plate structure 158 and bottom plate structure 159 of core layer 150 have lateral edge surfaces or ends that are substantially flush with lateral edges of the dielectric layer 151 of the core layer 150. That is, the ends of the top plate structure and bottom plate structure, respectively, terminate at the respective side edges of the core layer.

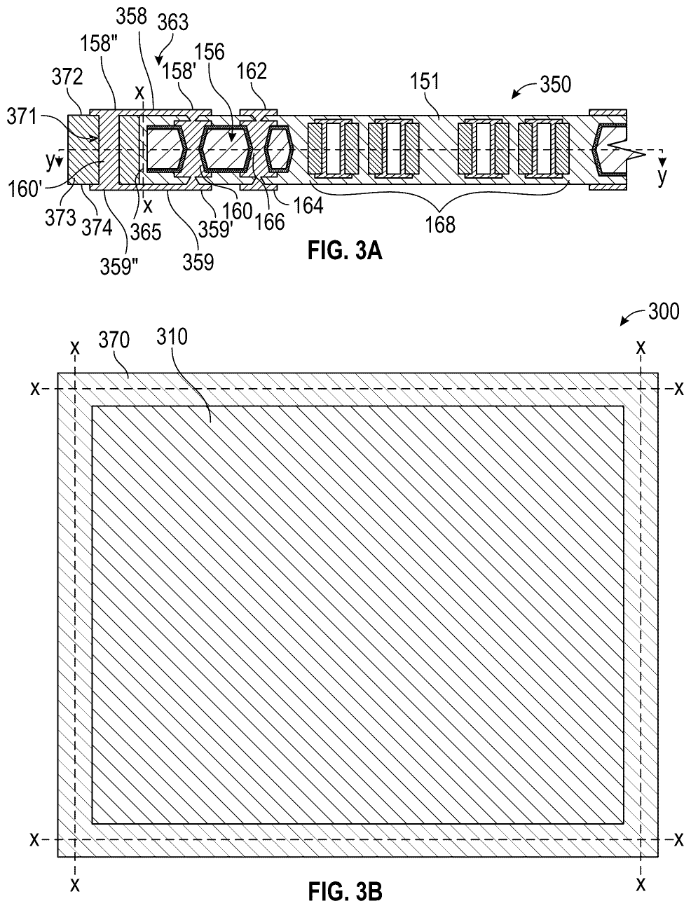

Advantageously, a clamp structure according to embodiments is to impart structural support to the core layer during fabrication of the same. The clamp structure may include a clamp material different from a material of the glass sheet 156. Preferably, the clamp material includes a material that is more ductile than a material of the glass sheet 156. More details regarding how the clamp structure imparts structural support to a core layer during fabrication of the same will be provided in relation to FIGS. 2A-2C and 3A below further below.

“Clamp material” as used herein is not to be construed to denote merely a single material. “Clamp material” may, as used herein, include one or more materials of the clamp.

According to a first embodiment for the clamp material, the clamp material may include an electrically conductive material, for example, a same material as that of the electrically conductive pathways of the core layer 150, such as a same material as that of active through-vias 166 and traces 162. The latter embodiment is suggested in FIG. 1.

According to a first option of this first embodiment for the clamp material, the clamp structure 163 is part of the electrically conductive pathways of the core layer 150, meaning that it is connected to conduct electrical signals within active (electrically active) regions of the core layer 150.

According to a second option of this first embodiment for the clamp material, the clamp structure 163, although made of an electrically conductive material, is a dummy structure, that is, not part of the electrically conductive pathways of the core layer 150. In such a case, the through-via 160 is a dummy via.

According to one embodiment, the clamp material includes a non-electrically conductive material, such as, for example, a dielectric material, such as an epoxy mold compound. For example, according to one embodiment, the clamp structure includes a mold compound similar to the mold compound of the dielectric layer 151 of the core layer 150.

According to one embodiment, the clamp material includes different materials, for example, an electrically conductive material and a dielectric material.

As seen in the embodiment of FIG. 1, the through-vias 166 and corresponding top and bottom traces 162 and 164 of electrically conductive pathways of core layer 150 are connected to vias 140 within respective ones of build-up layers 107a and 107b. If clamp structure 163 is also part of the electrically conductive pathways of core layer 150, it may be connected to vias or traces within adjacent build-up layers, either directly or indirectly through intervening components.

Let us now refer to FIGS. 2A-2E, which show respective reconstituted core layer panel structures (RPS) at various stages in the formation of glass core layers. An RPS may include a glass-containing panel substrate and an organic frame framing the glass-containing panel substrate. The glass-containing panel substrate includes a number of core layer portions that each include one or more glass sheets or glass substrate therein. FIGS. 2A-2C depict initial stages that may be used in the fabrication of glass core layers (after singulation of the ultimate resulting panel), some of which may be similar for example to core layer 150 of FIG. 1. For the formation of core layers according to some embodiments, however, stages alternative to those shown in FIGS. 2D and 2E may be used. It is to be noted that FIGS. 2A-2E depict panels in various stages of formation, the ultimate resulting panel (e.g., at FIG. 2E) to be singulated in order to result in a plurality of glass core layers. Thus, neither the scale nor the positioning of the vias 222, glass sheets 156, mold compound 205, dielectric layer 151 Coax Mils 168 depicted in FIGS. 2A-2E are to scale, and are merely to suggest the existence of such components within the respective panels of those figures, it being understood that those components are placed in much larger quantities across the panels in order to, upon singulation of the panel of FIG. 2E, result in a plurality of glass core layers, as would be recognized by one skilled in the art. In FIGS. 2A-2E, like components as compared with the core layer 150 of FIG. 1 are indicated with like reference numerals.

In FIG. 2A, a first stage for the fabrication of core layers according to some embodiments includes the provision of a RPS 200A which includes one or more glass sheets 156 similar to glass sheets 156 of FIG. 1, along with a glass sheet 156′ comparable to glass sheets 156, except that glass sheet 156′ is smaller and includes only one via therein. The glass sheets in RPS 200A include buffer layers thereon, and through-vias 202 similar to through-vias of core layer 150 of FIG. 1, although embodiments are not so limited. The RPS 200A further defines a cavity 201 between facing sides of the glass sheets 156 and 156′.

In FIG. 2B, a second stage for the fabrication of core layers according to some embodiments includes the provision of a RPS 200B. RPS 200B corresponds to the RPS 200A secured within an organic frame 270 that, in a top plan view of RPS 200B (see by way of example the organic frame 270 of FIG. 3B), would form a frame around the perimeter of the RPS 200A.

The organic frame may include, for example, an epoxy resin, a fiberglass-reinforced epoxy resin, an epoxy resin with inorganic fillers, a ceramic material, or a polymer material such as polyimide. For example, the organic frame may include one of a thermosetting resin such as an epoxy resin, a thermoplastic resin such as polyimide, or a material including the thermosetting resin and the thermoplastic resin, a glass fiber (or a glass cloth or a glass fabric, an inorganic filler, and/or a reinforcing material such as an inorganic filler, for example, a copper clad laminate (CCL), an unclad CCL, or the like). Alternatively, the organic may include, for example, a liquid crystal polymer (LCP).

In existing tools for the processing of the processing of panel structures that include a dielectric organic material without the inclusion of glass sheets therein, may include a dielectric layer (for example similar to the dielectric layer 151 of FIG. 1), along with vias, traces and any active or passive electronic components therein. Existing tools for the processing of such panel structures (such as for the provision of additional vias through the panel substrate, of additional active or passive components therein, of buildup layers thereon) are configured to directly grip the organic material of the panel substrate.

When a panel structure is provided that includes glass sheets that extend to edges thereof, if existing tools were to directly grip such glass sheets for the processing of the panel structure, disadvantageously, such an arrangement may result in cracking or breakage of the glass. Providing an RPS including an organic frame at a panel level at the perimeter of a glass-containing panel substrate advantageously prevents processing tool sets from directly handling the glass sheets, and allows the tool sets to handle the organic frame portion instead, in this way decreasing chances of breakage of glass sheets of glass sheets within the core layer. The provision of the organic frame 270 to create RPS 200B is part of a setup to further process RPS 200B while substantially decreasing chances of breaking the glass sheets.

In FIG. 2C, a third stage for the fabrication of core layers according to some embodiments includes the provision of a RPS 200C. RPS 200C corresponds to the RPS 200B with the addition of a dielectric material, such as mold compound 205 inside cavity 201 to fill empty spaces inside the inner perimeter of the organic frame 270. Mold compound 205 may correspond to the mold compound of dielectric layer 151 of FIG. 1. The mold compound 205 may be provided in any well-known manner, and may be cured to harden.

In FIG. 2D, a fourth stage for the fabrication of core layers includes the provision of a RPS 200D. RPS 200D corresponds to the RPS 200C, along with the provision of a metallization layers 204 and 204′ at respective top and bottom surfaces of the RPS 200C, which metallization layers provide contact with through-vias 202. The metallization layers may include any electrically conductive material as described herein, such as, for example, copper.

In FIG. 2E, a fifth stage for the fabrication of core layers includes the provision of a RPS 200E. RPS 200E corresponds to the RPS 200D, after patterning of metallization layers 204 and 204′ at respective top and bottom surfaces of the RPS 200D to provide corresponding traces 206 and 206′. RPS 200E further correspond to RPS 200D after provision therein of Coax Mils 168 (see FIG. 1), for example by way of hole drilling, followed by device formation/insertion. As noted previously, the processing of RPS 200D to result in RPS 200E may include the provision of any active or passive components in a well-known manner. RPS 200E includes the organic frame 270 framing a glass-containing panel substrate 210. RPS 200E may be singulated to result in a plurality of core layers according to the state of the art, where no clamp structure is present.

Reconstitution of a glass sub-panel (such as RPS 200A) into an organic frame (such as organic frame 270) as has been shown in the context of FIGS. 2A-2E enables core layers that include glass sheets therein to be fungible with existing organic tool sets or lines. However, still, the interface between the organic frame and the reconstituted medium (e.g., the interface between the dielectric material (such as mold compound 205) and organic frame 270) on one hand, and the glass material of the glass sheets on the other hand, present a weak mechanical point and tend to crack and delaminate during further processing of the glass sub-panel.

Some embodiments advantageously strengthen mechanical bonds between an organic frame and a glass sub-panel during manufacturing. Reference in this regard will now be made to FIGS. 3A and 3B.

In particular, FIG. 3A shows a portion of a core layer 350 similar to core layer 150 of FIG. 1. For example, the core layer 350 may be configured such that, if cut along plane X-X, it would result in the core layer 150 of FIG. 1, noting that plane X-X extends into a plane of the “page” of FIG. 3A. The same components of core layer 150 of FIG. 1 are indicated in FIG. 3A with the same reference numerals.

FIG. 3B shows a simplified cross-sectional to plan view of a RPS 300 that, when singulated, may result in a plurality of core layers according to one or more embodiments. FIG. 3B essentially shows that organic frame 370 frames a glass-containing panel substrate 310 (e.g., similar to glass-containing panel substrate 210 of FIG. 2E). The depiction in FIG. 3B is “simplified” in part because, for the sake of clarity, it omits the depiction of traces or plate structures shown in FIG. 3A. A singulation of the RPS 300 may result in the formation of a plurality of core layers, for example similar to core layer 350 of FIG. 3A.

The core layer 350 has a clamp structure 363 that, as opposed to the U-shaped clamp structure 163 of FIG. 1, defines a loop configuration in a vertical direction, clamp structure 363 looping around the interface 365 between the dielectric layer 151 and a block 373 that includes an organic material (“organic block”), and that corresponds to a portion of the organic frame 370 after singulation of the glass-containing panel substrate 310 (see FIG. 3B) to yield the core layer 350.

By “block” when referring to structural elements herein, what is meant is a solid body made of substantially a same material throughout.

Clamp structure 363 “clamps” (e.g., loops around, as seen in FIG. 3A) the shown glass sheet 156 and the block 373 together by way of through-vias 160 of glass sheet 156, by way of top plate structure 358 (which includes a glass-side plate structure portion 358′ and an organic frame-side structure portion 358″), by way of through-via 160′ extending through the block 373, and by way of bottom plate structure 359 (which includes a glass-side plate structure portion 359′ and an organic frame-side plate structure portion 359″). The top plate structure 358 and bottom plate structure 359 mechanically connect through-vias 160 and 160′ together. Clamp structure 363 may result in clamp structure 163 of FIG. 1 when the core layer 350 is cut along plane X-X, noting that clamp structure 163 corresponds to part of the loop configuration of clamp structure 363. In the clamp structure 363, the top and bottom plate structures 358 and 359 extend all the way to the through-via 160′ of the block 373, while in the clamp structure 163 of FIG. 1, the top and bottom plate structures 158 and 159 have lateral end surfaces that are substantially coextensive with lateral ends surfaces of the corresponding core layer.

More details regarding cutting along plane X-X to yield the embodiment of FIG. 1 will be provided further below.

According to some embodiments, at least one of the top plate structure or the bottom plate structure may include an electrically conductive material or a dielectric material or both.

Referring still to FIG. 3A, some embodiments include providing one or more through holes, such as through hole 371, extending between a top surface 372 and a bottom surface 374 of the organic frame 370. For example, an organic frame with through holes may be provided as at FIG. 2B, the cavity 201 filled with mold compound 205 as at FIG. 2C, and one or more through holes 371 (see FIG. 3A) provided in the organic frame of the RPS 200C of FIG. 2C. Thereafter, the one or more through holes 371 may be filled with a clamp material. As noted previously in relation to FIG. 1, the clamp material may include an electrically conductive material or a dielectric material, such as a mold compound similar to a dielectric layer 151. The provision of a clamp material to fill the one or more through holes 371 results in the formation of a RPS that is similar to RPS 200C in FIG. 2C, but that includes one or more organic frame through-vias 160′. If a plurality of organic frame through-vias 160′ are provided, they may be placed at various points at a periphery of the organic frame 370 at locations facing a corresponding through-via 160 of a nearest glass sheet 156. Thereafter, similar to the operations described in FIGS. 2D and 2E, a metallization layer may be provided at the top surface and at the bottom surface of the noted RPS, and patterned to form not only traces 162, but also top plate structures 358 and bottom plate structures 359.

As can be gleaned from FIG. 3A, the provision of clamp structures 363 at edges of a RPS imparts mechanical stability to the RPS by mechanically securing (akin to sewing) together the corresponding edge glass sheets 156 to their laterally facing organic frame 370, in this manner substantially reducing changes of delamination of the interface 365 and of breakage of the glass material of edge glass sheets 156 during processing of the RPS 300 within one or more tool sets that clamp the organic frame, such as during drilling for the inclusion of active or passive components therein, and such as during provision of buildup layers such as build up layer 107a-107e (see FIG. 1) thereon.

According to a second embodiment, core layer 350 may be used similar to core layer 150 of FIG. 1. In particular, according to a second embodiment, core layer 350 is not cut along planes X-X before being used as a core layer in a semiconductor assembly similar to microelectronic assembly 100 of FIG. 1. Referring to FIG. 3B, lateral planes X-X for cutting may exist at one or more sides of the RPS 300, only plane X-X having been shown in FIG. 3A by virtue of the fact that it shows a single core layer 350 and not an entire RPS. A second embodiment as described herein may thus include a core layer that includes the organic frame along with one or more clamp structures that have a looping configuration across a thickness (in a vertical direction as seen in FIG. 3A) of the core layer, where this core layer (e.g., core layer 350) may be used in a semiconductor assembly similar to that of FIG. 1. For example, core layer 350 of FIG. 3A may replace the core layer 150 of microelectronic assembly 100 of FIG. 1 according to this second embodiment.

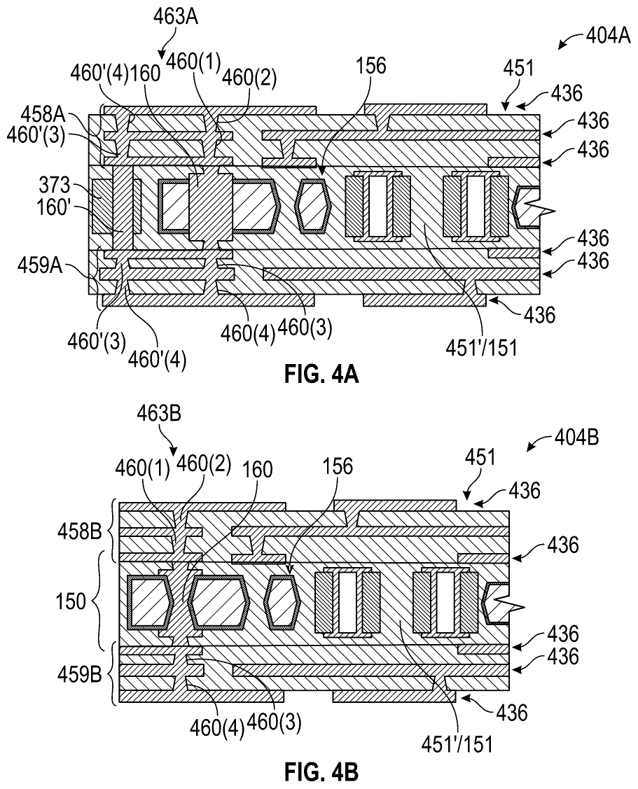

Referring now to FIGS. 4A and 4B, these figures show a third embodiment showing core layers 350 (of FIG. 3A) and 150 (of FIG. 1) respectively within package substrates 404A and package substrates 404B which include a multilayered clamp structure or nested clamp structure. In FIG. 4A, a core layer 350 similar to that of FIG. 3A is shown as having been provided with build-up layers above and below it to form the package substrate 404A, where the package substrate includes a multilayered clamp structure that includes multiple loops extending through block 373. In FIG. 4B, a core layer 150 similar to that of FIG. 1 is shown as having been provided with build-up layers above and below it to form the package substrate 404B, where the package substrate includes a multilayered clamp structure that includes multiple plate structures having end surfaces that are substantially flush with a lateral surface of the package substrate 404B. In FIGS. 4A and 4B, like components as compared with those of FIGS. 1 and 3A are indicated with like reference numerals.

A first embodiment of a multilayered clamp structure (corresponding to a first option of the third embodiment) includes: a first plurality of vertically stacked through-vias including a through-via extending through a glass sheet of the core layer, a second plurality of vertically stacked through-vias including a through-via extending through organic frame, a plurality of top plate structures and a plurality of bottom plate structures, where individual ones of top plate structures and individual ones of bottom plate structures are coupled to and at differing vertical distances as compared with one another from both the through-via of the glass sheet and the through-via of the organic frame.

For a multilayered clamp structure as described herein, a vertical distance between individual ones of a plurality of objects X (e.g., individual ones of the plurality of top plate structures) and an object Y (e.g., the through-via of” the glass sheet/the organic frame) is understood to be along an imaginary vertical line extending between a same point on object Y on one hand, and an intersection of the imaginary vertical line with a bottom surface of the individual ones of the plurality of objects X on the other hand.

For example, according to a first embodiment of a multilayered clamp structure as shown in FIG. 4A, the multilayered clamp structure 463A includes:
a first plurality of vertically stacked through-vias 160, 460(1), 460(2), 460(3) and 460′(4) including through-via 160 extending through the glass sheet 156 closest to the block 373;
a second plurality of vertically stacked through-vias 160′, 460′(1), 460′(2), 460′(3) and 460′(4) including through-via 160′ extending through the block 373;
a plurality of top plate structures 458A and a plurality of bottom plate structures 459A, where individual ones of top plate structures 458A and of bottom plate structures 459B are coupled to and at differing vertical distances as compared with one another from the through-via 160′ of the glass sheet and also from the through-via 160′ of the block 373.

A second embodiment of a multilayered clamp structure (corresponding to a second option of the third embodiment) includes: a plurality of vertically stacked through-vias including a through-via extending through a glass sheet of the core layer, a plurality of top plate structures and a plurality of bottom plate structures, where individual ones of top plate structures and individual ones of the bottom plate structures are coupled to and at differing vertical distances as compared with one another the through-via of the glass sheet.

For example, according to a second embodiment of a multilayered clamp structure as shown in FIG. 4B, the multilayered clamp structure 463B includes:
a plurality of vertically stacked through-vias 160, 460(1), 460(2), 460(3) and 460′(4) including through-via 160 extending through the glass sheet 156 closest to the block 373;
a plurality of top plate structures 458B and a plurality of bottom plate structures 459B, where individual ones of top plate structures 458B and of bottom plate structures 459B are coupled to and at differing vertical distances as compared with one another from the through-via 160′ of the glass sheet and also from the through-via 160′ of the block 373.

In both the first option of the third embodiment as shown in FIG. 4A and the second option of the third embodiment as shown in FIG. 4B, the core layer includes multiple metallization layers or traces 436, some of which may correspond to traces 136 of FIG. 1, the traces 436 embedded in multiple dielectric layers making up dielectric layer 451 of package substrates 404A and 404B. The dielectric layer 451 in the shown embodiments of FIGS. 4A and 4B includes a dielectric layer 451′, which in its configuration, is similar to the configuration of the dielectric layer 151 of the core layer 150 of FIG. 1 or of the dielectric layer 151 of the core layer 350 of FIG. 3A. The dielectric layer 451 may include any dielectric material as set forth above in relation to the dielectric material of core layer 150 of FIG. 1 or 3A, or of build-up layers 107a-107e of FIG. 1.

For example, dielectric layers of dielectric layer 451 of the package substrates 404A and 404B that are above and below the dielectric layer 151 may correspond to respective ones of the dielectric layers within build-up layers 107a-107e in FIG. 1, with the exception that, at each successive build-up layer in FIGS. 4A and 4B, there is either a plate structure connected to both a through-via of a glass sheet of the core layer and to a through-via in the organic frame (e.g., FIG. 4A) or a plate structure connected to a through-via of a glass sheet of the core and having an end coextensive with the side surface of the corresponding core layer (e.g., FIG. 4B).

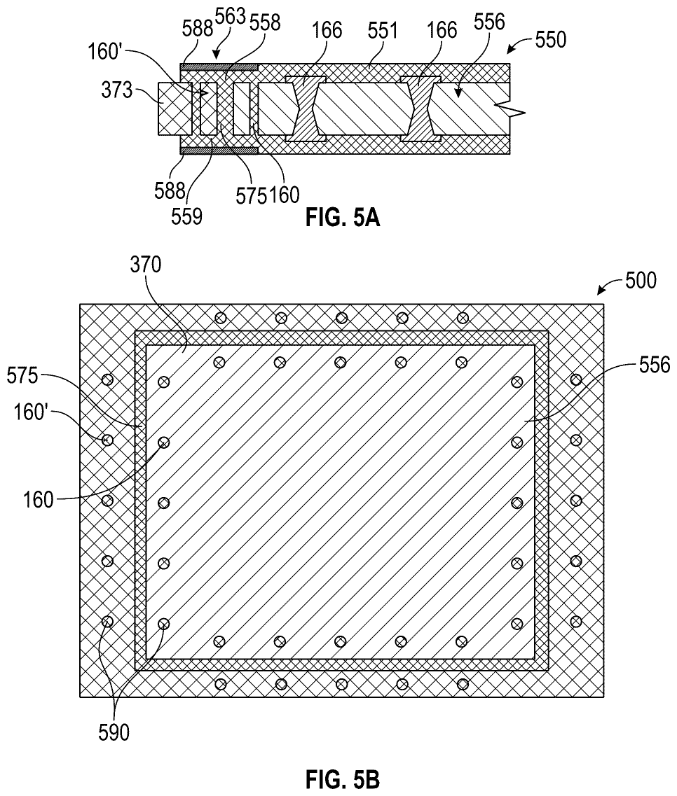

Referring now to FIGS. 5A and 5B, these figures show a fourth embodiment showing with a clamp structure which is made of dielectric materials. In FIGS. 5A and 5B, like components as compared with those of FIG. 1 and FIG. 3A are indicated with like reference numerals. FIG. 5A is a cross sectional view of core layer 550 similar to the views of FIGS. 3A, 4A and 4B, while FIG. 5B is a cross sectional view along a plane parallel to and between a top surface and a bottom surface of a RPS 500, where RPS 500 includes a plurality of core layer structures at the perimeter thereof that would yield, after singulation, core layers similar to core layer 550 of FIG. 5A.

In FIG. 5A, a core layer 550 includes active through-vias 166 extending through glass sheet 556, an block 373 facing an outer lateral surface of the glass sheet 556, a dielectric layer 551 including a dielectric material similar to that of dielectric layer 151 of FIG. 1, and a clamp structure 563 on each side of the core layer 550. In the embodiment of FIG. 5A, clamp structure 563 includes a through-via 160 extending through the glass material of the glass sheet 556, a through-via 160′ extending through the block 373, top plate structure 558 and bottom plate structure 559 connecting the through-vias 160 and 160′ together. In the embodiment of FIG. 5A, the clamp material includes a dielectric material. Optionally the clamp material may include a same dielectric material a mold material of the core layer, as suggested by dielectric layer 551 extending into through-vias 160 and 160′, extending above the through-vias 160 and 160′ to form top and bottom plate structures 558 and 559, and further extending into a space between the glass sheet 556 and the block 373 to form a dielectric frame 575 at the perimeter of glass sheet 556, as best suggested in FIG. 5B. According to the embodiment of FIGS. 5A and 5B, strips 588 may be provided to extend along a length of individual ones of the plate structures 558 and 559 in order to impart further mechanical stability to clamp structure 563. Strips 588 may include one or more of a glass cloth material, a metal material (such as a same material as a material used for traces) or any other rigid material to reinforce a mechanical strength and stability of the clamp structure 563.

Referring now in particular to FIG. 5B, RPS 500 is shown as including a plurality of pairs 590 of through-vias scattered around a perimeter of the RPS 500, with each pair including a through-via 160 facing a corresponding through-via 160′ through organic frame 370. Each pair 590 may be part of a corresponding clamp structure similar to clamp structure 563 of FIG. 5A, where individual through-vias 160 and 160′ of each pair are connected by way of top and bottom plate structures 558 and 559 as shown in FIG. 5A.

Advantageously, core layers according to some embodiments enhance a debonding margin of reconstituted panels (a combination of glass containing core layers and an organic frame surrounding the same) by incorporating a series of through-holes in the organic frame and glass sheets of the core layer around the panel/core layer periphery. These holes are filled during a reconstitution stage, forming through-vias that are part of chains or loops around gap regions between the glass sheets and the organic frame in order to provide additional mechanical anchoring and improve the debonding margin. This approach is particularly beneficial for reconstituted panels with thin glass containing core layers, mitigating the risk of debonding during initial layer processing.

A “debonding margin” as referred to herein in the context of a glass sheet and an organic frame refers to a safety margin or buffer that prevents the separation (debonding) of the glass sheet from the organic frame bonded to it during processing. In the context of reconstituted panels, it is the tolerance or capability of the bonded interface between different materials (such as glass and a frame) to withstand stress, strain, or other forces without separating. Advantageously, some embodiments enhance the debond margin by improving the robustness and reliability of the bonded interface, reducing the likelihood of debonding during manufacturing. The through-vias on the glass sheet can serve as a protective barrier (similar to a moat) during a dicing process to form a core layer from a panel, such as during a QuickPath dicing process. This protective barrier helps to improve the margin of error or safety buffer that prevents defects or damage to the panel during the dicing process. Essentially, the through-vias of the glass sheets at the periphery of a panel provide additional structural support and isolation, reducing the risk of damage and enhancing the overall integrity of the panel during cutting and handling.

For any of the embodiments described herein, a core layer may include one or more clamp structures which may be provided at any edge location of the core layer.

For any of the embodiments described herein, an RPS may include one or more clamp structures which may be provided at any part of a perimeter thereof.

FIG. 6 shows an RPS 600 according to the state of the art, where the glass sheet 656 and the organic frame 670 are embedded in a mold portion 651, and where top and bottom facing edge surfaces of the glass sheet 656 and organic frame 670 are joined together by way of glass cloths 688. A tool T may grip the organic frame 670 at regions indicated in FIG. 6 in order for the RPS to be further processed. The embodiment of FIG. 6, however, disadvantageously, does not ensure the mechanical stability and reinforcement provided by any of the clamp structures described herein. Thus, the proposed solution of FIG. 6 may still be subject to crack/delamination. Additionally, disadvantageously, such an approach results in significant protrusion on the edges of the panel, which can make handling difficult/problematic.

Advantageously, some embodiments enhance the debond margin of reconstituted panels/RPS.' Some embodiments propose providing through-holes in both the organic frame and the glass sheets of a RPS around the RPS' edges. During the reconstitution process, these holes may be filled, creating chains or loops around the interfaces or gaps between the organic frame and the glass sheets, providing additional mechanical anchoring and thereby increasing the debond margin, thus providing a buffer that prevents material separation under stress during processing of the RPS. This enhancement is particularly beneficial for panels with thin glass sheets, which are more susceptible to debonding during initial processing stages.

Advantageously, the filled through-holes offer superior mechanical support, significantly reducing the risk of debonding. By improving the debond margin, some embodiments make it possible for thin-core reconstituted panels to maintain their integrity during the early layers of processing, leading to higher reliability and fewer defects. Additionally, the through-holes on the glass core side serve a dual purpose. They act as a protective barrier, referred to as a moat, during the QuickPath (QP) dicing process. This helps improve the safety margin that prevents defects or damage during dicing.

Advantageously, some embodiments not only strengthen the bond between a glass sheet and an organic frame of a RPS, especially in thin-core panels, but also enhance overall processing stability and product quality by improving both the debond and seware margins, resulting in a robust and reliable manufacturing process for RPS.'

Advantageously, some embodiments reduce the risk of delamination or cracking in RPSs, imparting better strength between the RPS' organic frame, mold compound, and glass sheets.

Advantageously, a clamp structure according to some embodiments may be fabricated in-situ with metal layers at panel/RPS level, and would not necessarily require significant modification to current processing.

Advantageously, some embodiments provide a multi-layered clamp structure resulting from multiple loops, wherein the loops extend into build up layers for additional strength.

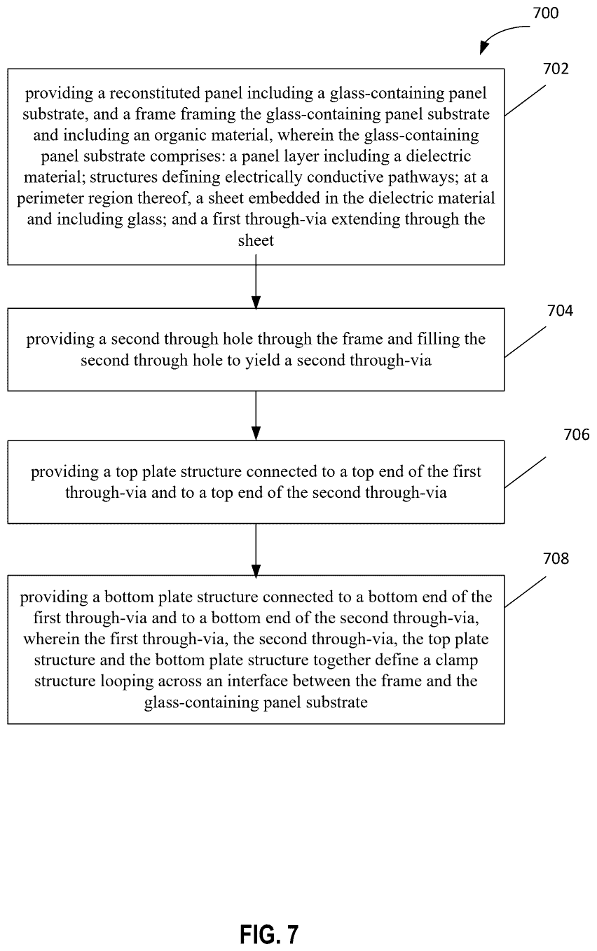

FIG. 7 is a flowchart of a process 700 according to some embodiments. At operation 702, the process includes providing a reconstituted panel including a glass-containing panel substrate, and a frame framing the glass-containing panel substrate and including an organic material, wherein the glass-containing panel substrate comprises: a panel layer including a dielectric material; structures defining electrically conductive pathways; at a perimeter region thereof, a sheet embedded in the dielectric material and including glass; and a first through-via extending through the sheet. At operation 704, the process includes providing a second through hole through the frame and filling the second through hole to yield a second through-via. At operation 706, the process includes providing a top plate structure connected to a top end of the first through-via and to a top end of the second through-via. At operation 708, the process includes providing a bottom plate structure connected to a bottom end of the first through-via and to a bottom end of the second through-via, wherein the first through-via, the second through-via, the top plate structure and the bottom plate structure together define a clamp structure looping across an interface between the frame and the glass-containing panel substrate.

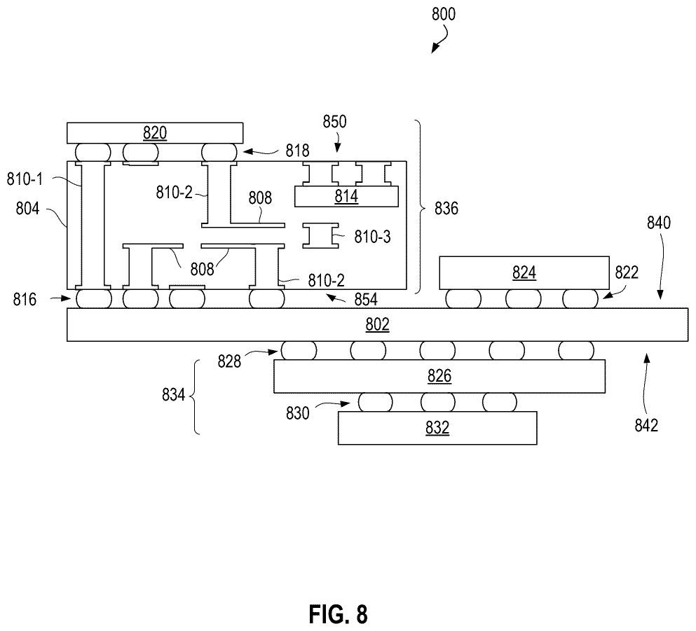

FIG. 8 is a cross-sectional side view of an integrated circuit device assembly 800 that may include one or more integrated circuit structures each including any of the microelectronic assemblies such as semiconductor packages of embodiments described herein. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may include an integrated circuit structure including an interconnect structure as described herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

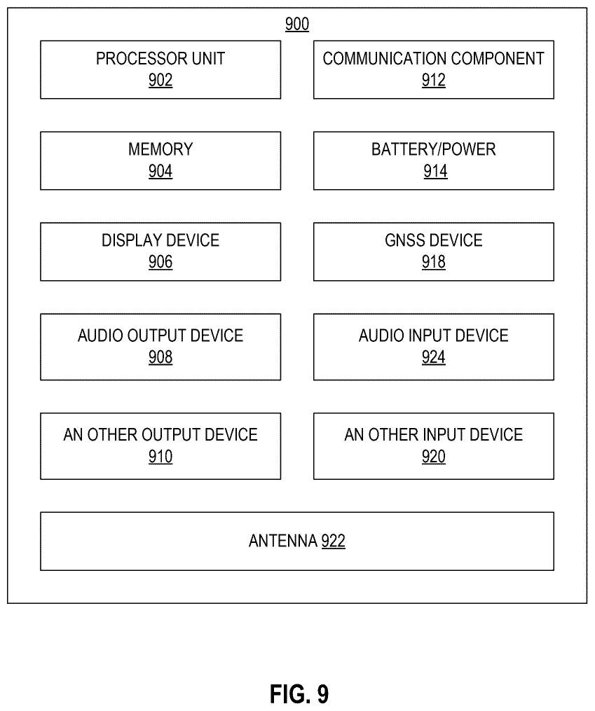

FIG. 9 is a block diagram of an example electrical device 900 that may include one or more of the embodiment semiconductor packages disclosed herein. For example, any suitable ones of the components of the electrical device 900 may include one or more of the integrated circuit device assemblies 800, integrated circuit components 820, and/or embodiment semiconductor packages disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit,” “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include one or more antennas, such as antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include another output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include another input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

In the instant description, “the As are coupled to the Bs” means that at least some of the As are coupled to at least some of the Bs, and not necessarily that all As are coupled to at least one B and all Bs are coupled to at least one A.

In the instant description, “A is within B” means that at least some of A is encompassed within the physical boundaries of B.

The use of reference numerals separated by a “/”, such as “102/104” for example, is intended to refer to 102 or 104 as appropriate. Otherwise, the forward slash (“/”) as used herein means “and/or.”

When used to describe a range of dimensions, the phrase “between X and Y” represents a range that includes X and Y. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one semiconductor package including an embedded magnetic inductor.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e., one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the terms “coupled” or “connected” mean a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner, and are not intended to imply that the objects so described must necessarily be made of different materials or have different dimensions.

For purposes of the embodiments, any transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### EXAMPLES

Some non-limiting example embodiments are set forth below.

Example 1 includes a core layer a package substrate, the core layer including: a dielectric layer; a sheet including glass, the sheet encapsulated in the dielectric layer; structures defining electrically conductive pathways within the core layer; and a clamp structure including a through-via extending through the sheet, a top plate structure connected to a top end of the through-via, and a bottom plate structure connected to a bottom end of the through-via, wherein one of: the top plate structure and the bottom plate structure have respective lateral end surfaces that are substantially flush with a lateral edge surface of the core layer; or the through-via is a first through-via, the core layer includes a block at an edge region thereof, the block defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via.

Example 2 includes the subject matter of Example 1, wherein the clamp structure includes a clamp material, the clamp material including at least one of an electrically conductive material or a dielectric material.

Example 3 includes the subject matter of any one of Examples 1-2, wherein the dielectric layer includes a mold compound.

Example 4 includes the subject matter of any one of Examples 1-3, wherein the glass includes silicon, and at least one of oxygen or boron, and the organic material includes at least one of an epoxy resin, a ceramic material or a polymer material.

Example 5 includes the subject matter of any one of Examples 1-4, wherein the electrically conductive pathways include the clamp structure.

Example 6 includes the subject matter of any one of Examples 1-4, wherein the first through-via and the second through-via are dummy vias.

Example 7 includes the subject matter of any one of Examples 1-4 and 6, wherein the clamp structure includes an epoxy mold compound.

Example 8 includes the subject matter of any one of Examples 1-4, 6 and 7, wherein the clamp structure and the dielectric layer are made of identical materials with respect to one another.

Example 9 includes the subject matter of any one of Examples 1-8, wherein the block and the dielectric layer are made of different materials with respect to one another.

Example 10 includes the subject matter of any one of Examples 1-9, further including a first strip on the top plate structure and a second strip on the bottom plate structure, individual ones of the first strip and the second strip including at least one of a glass cloth material or a metal.

Example 11 includes a package substrate including: a core layer of a package substrate, the core layer including: a dielectric layer; a sheet including glass and encapsulated in the dielectric layer; and structures defining electrically conductive pathways within the core layer; a clamp structure including a through-via extending through the sheet, a top plate structure connected to a top end of the through-via, and a bottom plate structure connected to a bottom end of the through-via, wherein one of: the top plate structure and the bottom plate structure have respective lateral end surfaces that are substantially flush with a lateral edge surface of the package substrate; or the through-via is a first through-via, the core layer includes a block at an edge region thereof, the block defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via; and a plurality of build-up layers on at least one of a top surface or a bottom surface of the core layer, the plurality of build-up layers electrically coupled to the electrically conductive pathways of the core layer.

Example 12 includes the subject matter of Example 11, wherein the clamp structure includes a clamp material, the clamp material including at least one of an electrically conductive material or a dielectric material.

Example 13 includes the subject matter of any one of Examples 11-12, wherein the dielectric layer includes a mold compound.

Example 14 includes the subject matter of any one of Examples 11-13, wherein the glass includes silicon, and at least one of oxygen or boron, and the organic material includes at least one of an epoxy resin, a ceramic material or a polymer material.

Example 15 includes the subject matter of any one of Examples 11-14, wherein the electrically conductive pathways include the clamp structure.

Example 16 includes the subject matter of any one of Examples 11-14, wherein the first through-via and the second through-via are dummy vias.

Example 17 includes the subject matter of any one of Examples 11-14 and 16, wherein the clamp structure includes an epoxy mold compound.

Example 18 includes the subject matter of any one of Examples 11-14, 16 and 17, wherein the clamp structure includes a same material as a material of the dielectric layer.

Example 19 includes the subject matter of any one of Examples 11-18, further including a first strip on the top plate structure and a second strip on the bottom plate structure, individual ones of the first strip and the second strip including at least one of a glass cloth material or a metal.

Example 20 includes the subject matter of any one of Examples 11-19, wherein the top plate structure and the bottom plate structure are in respective ones of the plurality of build-up layers.

Example 21 includes the subject matter of any one of Examples 11-19, wherein the clamp structure is a multilayered clamp structure.

Example 22 includes the subject matter of Example 21, wherein the multilayered clamp structure includes: a first plurality of vertically connected through-vias including the first through-via; a second plurality of vertically connected through-vias including the second through-via; a plurality of top plate structures including the top plate structure, individual ones of the plurality of top plate structures coupled to and at differing vertical distances as compared with one another from the first through-via and from the second through-via; and a plurality of bottom plate structures including the bottom plate structure, individual ones of the plurality of bottom plate structures coupled to and at differing vertical distances as compared with one another from the first through-via and from the second through-via.

Example 23 includes the subject matter of Example 21, wherein the multilayered clamp structure includes: a first plurality of vertically connected through-vias including the first through-via; a second plurality of vertically connected through-vias including the second through-via; a plurality of top plate structures including the top plate structure, individual ones of the plurality of top plate structures coupled to and at differing vertical distances as compared with one another from the first through-via; and a plurality of bottom plate structures including the bottom plate structure, individual ones of the plurality of bottom plate structures coupled to and at differing vertical distances as compared with one another from the first through-via.

Example 24 includes a microelectronic assembly including: a package substrate including: a core layer of a package substrate, the core layer including: a dielectric layer; a sheet including glass and encapsulated in the dielectric layer; and structures defining electrically conductive pathways within the core layer; a clamp structure including a through-via extending through the sheet, a top plate structure connected to a top end of the through-via, and a bottom plate structure connected to a bottom end of the through-via, wherein one of: the top plate structure and the bottom plate structure have respective lateral end surfaces that are substantially flush with a lateral edge surface of the package substrate; or the through-via is a first through-via, the core layer includes a block at an edge region thereof, the block defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via; and a plurality of build-up layers on at least one of a top surface or a bottom surface of the core layer, the plurality of build-up layers electrically coupled to the electrically conductive pathways of the core layer; and microelectronic dies electrically coupled to at least one of the plurality of build-up layers.

Example 25 includes the subject matter of Example 24, wherein the clamp structure includes a clamp material, the clamp material including at least one of an electrically conductive material or a dielectric material.

Example 26 includes the subject matter of any one of Examples 24-25, wherein the dielectric layer includes a mold compound.

Example 27 includes the subject matter of any one of Examples 24-26, wherein the glass includes silicon, and at least one of oxygen or boron, and the organic material includes at least one of an epoxy resin, a ceramic material or a polymer material.

Example 28 includes the subject matter of any one of Examples 24-27, wherein the electrically conductive pathways include the clamp structure.

Example 29 includes the subject matter of any one of Examples 24-27, wherein the first through-via and the second through-via are dummy vias.

Example 30 includes the subject matter of any one of Examples 24-27 and 29, wherein the clamp structure includes an epoxy mold compound.

Example 31 includes the subject matter of any one of Examples 24-27, 29 and 30, wherein the clamp structure includes a same material as a material of the dielectric layer.

Example 32 includes the subject matter of any one of Examples 24-31, further including a first strip on the top plate structure and a second strip on the bottom plate structure, individual ones of the first strip and the second strip including at least one of a glass cloth material or a metal.

Example 33 includes the subject matter of any one of Examples 24-32, wherein the top plate structure and the bottom plate structure are in respective ones of the plurality of build-up layers.

Example 34 includes the subject matter of any one of Examples 24-32, wherein the clamp structure is a multilayered clamp structure.

Example 35 includes the subject matter of Example 34, wherein the multilayered clamp structure includes: a first plurality of vertically connected through-vias including the first through-via; a second plurality of vertically connected through-vias including the second through-via; a plurality of top plate structures including the top plate structure, individual ones of the plurality of top plate structures coupled to and at differing vertical distances as compared with one another from the first through-via and from the second through-via; and a plurality of bottom plate structures including the bottom plate structure, individual ones of the plurality of bottom plate structures coupled to and at differing vertical distances as compared with one another from the first through-via and from the second through-via.

Example 36 includes the subject matter of Example 34, wherein the multilayered clamp structure includes: a first plurality of vertically connected through-vias including the first through-via; a second plurality of vertically connected through-vias including the second through-via; and a plurality of top plate structures including the top plate structure, individual ones of the plurality of top plate structures coupled to and at differing vertical distances as compared with one another from the first through-via; and a plurality of bottom plate structures including the bottom plate structure, individual ones of the plurality of bottom plate structures coupled to and at differing vertical distances as compared with one another from the first through-via.

Example 37 includes the subject matter of any one of Examples 24-26, further including a printed circuit board, the package substrate electrically coupled to the printed circuit board.

Example 38 includes a method including: providing a reconstituted panel including a glass-containing panel substrate, and a frame framing the glass-containing panel substrate and including an organic material, wherein the glass-containing panel substrate comprises: a panel layer including a dielectric material; structures defining electrically conductive pathways; at a perimeter region thereof, a sheet embedded in the dielectric material and including glass; and a first through-via extending through the sheet; providing a second through hole through the frame and filling the second through hole to yield a second through-via; providing a top plate structure connected to a top end of the first through-via and to a top end of the second through-via; providing a bottom plate structure connected to a bottom end of the first through-via and to a bottom end of the second through-via, wherein the first through-via, the second through-via, the top plate structure and the bottom plate structure together define a clamp structure looping across an interface between the frame and the glass-containing panel substrate.

Example 39 includes the subject matter of Example 38, further including providing a core layer including some of the electrically conductive pathways, the sheet and the clamp structure, providing the core layer including singulating the reconstituted panel.

Example 40 includes the subject matter of Example 38, wherein the clamp structure is a first clamp structure, the top plate structure is a first top plate structure, and the bottom plate structure is a first bottom plate structure, the method further including providing a core layer including the sheet by: cutting vertically across the frame to cut vertically across the first top plate structure yielding a second top plate structure, and to cut vertically across the first bottom plate structure yielding a second bottom plate structure; and singulating the reconstituted panel to yield the core layer, the core layer including a second clamp structure that comprises the second top plate structure, the first through-via, and the second bottom plate structure, wherein the second top plate structure and the second bottom plate structure have respective lateral end surfaces that are substantially flush with a lateral edge surface of the core layer, the core layer including some of the electrically conductive pathways.

Example 41 includes the subject matter of any one of Examples 38-39, wherein the clamp structure includes a clamp material, the clamp material including at least one of an electrically conductive material or a dielectric material.

Example 42 includes the subject matter of any one of Examples 38-41, wherein the dielectric material includes a mold compound.

Example 43 includes the subject matter of any one of Examples 38-42, wherein the glass includes silicon, and at least one of oxygen or boron, and the organic material includes at least one of an epoxy resin, a ceramic material or a polymer material.

Example 44 includes the subject matter of any one of Examples 38-39, wherein the electrically conductive pathways include the clamp structure.

Example 45 includes the subject matter of any one of Examples 38-44, wherein the first through-via and the second through-via are dummy vias.

Example 46 includes the subject matter of any one of Examples 38-39, wherein the clamp structure includes an epoxy mold compound.

Example 47 includes the subject matter of any one of Examples 38-39, wherein the clamp structure and the panel layer are made of identical materials with respect to one another.

Example 48 includes the subject matter of any one of Examples 38-47, wherein the frame and the panel layer are made of different materials with respect to one another.

Example 49 includes the subject matter of any one of Examples 38-39, further including a first strip on the top plate structure and a second strip on the bottom plate structure, individual ones of the first strip and the second strip including at least one of a glass cloth material or a metal.

Example 50 includes the subject matter of any one of Examples 38-49, further including providing a plurality of build-up layers on at least one of a top surface or a bottom surface of the panel layer, the plurality of build-up layers electrically coupled to the electrically conductive pathways.

Example 51 includes the subject matter of any one of Examples 38-39, wherein the clamp structure is a multilayered clamp structure.

Example 52 includes the subject matter of Example 51, wherein the multilayered clamp structure includes: a first plurality of vertically connected through-vias including the first through-via; a second plurality of vertically connected through-vias including the second through-via; a plurality of top plate structures including the top plate structure, individual ones of the plurality of top plate structures coupled to and at differing vertical distances as compared with one another from the first through-via and from the second through-via; and a plurality of bottom plate structures including the bottom plate structure, individual ones of the plurality bottom plate structures coupled to and at differing vertical distances as compared with one another from the first through-via and from the second through-via.

Example 53 includes the subject matter of Example 40, wherein the second clamp structure is a multilayered clamp structure that includes: a first plurality of vertically connected through-vias including the first through-via; a second plurality of vertically connected through-vias including the second through-via; and a plurality of top plate structures including the top plate structure, individual ones of the plurality of top plate structures coupled to and at differing vertical distances as compared with one another from the first through-via; and a plurality of bottom plate structures including the bottom plate structure, individual ones of the plurality of bottom plate structures coupled to and at differing vertical distances as compared with one another from the first through-via.

What is claimed is:

1. A core layer of a package substrate, the core layer including:
a dielectric layer;
a sheet including glass, the sheet encapsulated in the dielectric layer;
structures defining electrically conductive pathways within the core layer; and
a clamp structure including a through-via extending through the sheet, a top plate structure connected to a top end of the through-via, and a bottom plate structure connected to a bottom end of the through-via, wherein one of:
the top plate structure and the bottom plate structure have respective lateral end surfaces that are substantially flush with a lateral edge surface of the core layer; or
the through-via is a first through-via, the core layer includes a block at an edge region thereof, the block defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via.

2. The core layer of claim 1, wherein the clamp structure includes a clamp material, the clamp material including at least one of an electrically conductive material or a dielectric material.

3. The core layer of claim 1, wherein the dielectric layer includes a mold compound.

4. The core layer of claim 1, wherein the glass includes silicon, and at least one of oxygen or boron, and the organic material includes at least one of an epoxy resin, a ceramic material or a polymer material.

5. The core layer of claim 1, wherein the electrically conductive pathways include the clamp structure.

6. The core layer of claim 1, wherein the first through-via and the second through-via are dummy vias.

7. The core layer of claim 1, wherein the clamp structure and the dielectric layer are made of identical materials with respect to one another.

8. The core layer of claim 1, wherein the block and the dielectric layer are made of different materials with respect to one another.

9. The core layer of claim 1, further including a first strip on the top plate structure and a second strip on the bottom plate structure, individual ones of the first strip and the second strip including at least one of a glass cloth material or a metal.

10. A package substrate including:
a core layer of a package substrate, the core layer including:
a dielectric layer;
a sheet including glass and encapsulated in the dielectric layer; and
structures defining electrically conductive pathways within the core layer;
a clamp structure including a through-via extending through the sheet, a top plate structure connected to a top end of the through-via, and a bottom plate structure connected to a bottom end of the through-via, wherein one of:
the top plate structure and the bottom plate structure have respective lateral end surfaces that are substantially flush with a lateral edge surface of the package substrate; or
the through-via is a first through-via, the core layer includes a block at an edge region thereof, the block defines an interface with the dielectric layer and includes an organic material, the clamp structure includes a second through-via extending through the block, the top plate structure is connected to top ends of respective ones of the first through-via and the second through-via, and the bottom plate structure is connected to bottom ends of respective ones of the first through-via and the second through-via; and
a plurality of build-up layers on at least one of a top surface or a bottom surface of the core layer, the plurality of build-up layers electrically coupled to the electrically conductive pathways of the core layer.

11. The package substrate of claim 10, wherein the clamp structure includes a clamp material, the clamp material including at least one of an electrically conductive material or a dielectric material.

12. The package substrate of claim 10, wherein the electrically conductive pathways include the clamp structure.

13. The package substrate of claim 10, wherein the first through-via and the second through-via are dummy vias.

14. The package substrate of claim 10, wherein the clamp structure includes a same material as a material of the dielectric layer.

15. The package substrate of claim 10, wherein the block and the dielectric layer are made of different materials with respect to one another.

16. The package substrate of claim 10, further including a first strip on the top plate structure and a second strip on the bottom plate structure, individual ones of the first strip and the second strip including at least one of a glass cloth material or a metal.

17. A method including:
providing a reconstituted panel including a glass-containing panel substrate, and a frame framing the glass-containing panel substrate and including an organic material, wherein the glass-containing panel substrate comprises:
a panel layer including a dielectric material;
structures defining electrically conductive pathways;
at a perimeter region thereof, a sheet embedded in the dielectric material and including glass; and
a first through-via extending through the sheet;
providing a second through hole through the frame and filling the second through hole to yield a second through-via;
providing a top plate structure connected to a top end of the first through-via and to a top end of the second through-via; and
providing a bottom plate structure connected to a bottom end of the first through-via and to a bottom end of the second through-via, wherein the first through-via, the second through-via, the top plate structure and the bottom plate structure together define a clamp structure looping across an interface between the frame and the glass-containing panel substrate.

18. The method of claim 17, further including providing a core layer including some of the electrically conductive pathways, the sheet and the clamp structure, providing the core layer including singulating the reconstituted panel.

19. The method of claim 17, wherein the clamp structure is a first clamp structure, the top plate structure is a first top plate structure, and the bottom plate structure is a first bottom plate structure, the method further including providing a core layer including the sheet by:
cutting vertically across the frame to cut vertically across the first top plate structure yielding a second top plate structure, and to cut vertically across the first bottom plate structure yielding a second bottom plate structure; and
singulating the reconstituted panel to yield the core layer, the core layer including a second clamp structure that comprises the second top plate structure, the first through-via, and the second bottom plate structure, wherein the second top plate structure and the second bottom plate structure have respective lateral end surfaces that are substantially flush with a lateral edge surface of the core layer, the core layer including some of the electrically conductive pathways.

20. The method of claim 17, further including providing a first strip on the top plate structure and a second strip on the bottom plate structure, individual ones of the first strip and the second strip including at least one of a glass cloth material or a metal.
